(19) United States
(12) Patent Application Publication
(10) Pub. No.: US 2013/0027092 A1
(43) Pub. Date: Jan. 31, 2013

(54) Digital Output Driver

(71) Applicant: David E. Bien, Glendale, AZ (US)

(72) Inventor: David E. Bien, Glendale, AZ (US)

(73) Assignee: FUJITSU SEMICONDUCTOR LIMITED, Kanagawa (JP)

(21) Appl. No.: 13/193,003

(22) Filed: Jul. 28, 2011

(51) Int. Cl. H03K 3/353

(52) U.S. Cl. 327/109

(57) ABSTRACT

A digital output driver is disclosed. In accordance with some embodiments of the present disclosure, a digital output driver may comprise at least one of an output-source PMOS configured to source current during at least a portion of a low-to-high transition of a digital output, wherein the output-source PMOS is configured to mirror a reference PMOS configured to be driven at its gate by a first amplifier and to be biased by a first reference current, and an output-sink NMOS configured to sink current during at least a portion of a high-to-low transition of the digital output, wherein the output-sink NMOS is configured to mirror a reference NMOS configured to be driven at its gate by a second amplifier and to be biased by a second reference current.

### TECHNICAL FIELD

The present disclosure relates generally to electronic circuits and, more particularly, to digital output drivers.

### BACKGROUND

Integrated circuits may include digital output drivers configured to communicate digital signals to other integrated circuits. A digital output driver may be configured to drive a range of capacitive loads depending on the number of other devices to which it may be coupled. In order to facilitate compatibility with various types of devices that may need to digitally communicate with each other in various applications, devices may include digital output drivers that adhere to industry-standard specifications.

One example of industry-standard specification for digital communication between devices is the Radio Frequency Front-End Control Interface (RFFE) specification as developed by the MIPI Alliance. The mobile radio communications industry is trending toward complex radio devices, which may have several parallel transceivers along with multiple front-end devices. Front-end devices may include, for example, power amplifiers, low-noise amplifiers, power management devices, filters, switches, tuners, and/or sensors. Various front-end devices may be incorporated on a single integrated circuit or located on separate integrated circuits and coupled together via off-chip routing. As the complexity and the number of devices in modern mobile radio systems increases, digital output drivers incorporated on various front-end devices must be capable of communicating with a larger number of other devices and, thus, must be capable of driving a wide range of potential capacitive loads while meeting industry-standard ranges for digital signal transition times.

### SUMMARY

In accordance with some embodiments of the present disclosure, a digital output driver may comprise a pre-driver configured to receive a digital input signal, drive a first p-type Metal-Oxide Semiconductor Field Effect Transistor (PMOS) based at least on the digital input signal, and drive a first n-type Metal-Oxide Semiconductor Field Effect Transistor (NMOS) based at least on the digital input signal, and at least one of an output-source PMOS configured to provide an output-source current during at least a portion of a low-to-high transition of an output of the digital output driver, wherein the output-source PMOS is configured to mirror a reference PMOS that is configured to be driven at its gate by a first amplifier, to be biased by a first reference current, and to be cascoded by a cascode PMOS, and an output-sink NMOS configured to provide an output-sink current during at least a portion of a high-to-low transition of the output of the digital output driver, wherein the output-sink NMOS is configured to mirror a reference NMOS that is configured to be driven at its gate by a second amplifier, to be biased by a second reference current, and to be cascoded by a cascode NMOS.

Technical advantages of the present disclosure may be readily apparent to one skilled in the art from the figures, description and claims included herein.

### BRIEF DESCRIPTION OF THE DRAWINGS

FIG. 1 illustrates a schematic diagram of an example digital output driver as known in the art;

FIG. 2 illustrates a schematic diagram of a digital output driver, in accordance with certain embodiments of the present disclosure; and

FIG. 3 illustrates a flow chart of a method for driving a digital output with a capacitive load.

### DETAILED DESCRIPTION

The present disclosure may refer to the “size” of various types of transistors, including an n-type metal-oxide semiconductor field-effect transistor (NMOS), and a p-type metal-oxide semiconductor field-effect transistor (PMOS). Unless otherwise specified, the description of a transistor's size, as used herein, describes the size parameter that affects transistor characteristics such as the transconductance and output current of the transistor. For example, for PMOS and NMOS devices, “size” may refer to the width-to-length ratio of the gate and/or conducting channel of the device. Accordingly, devices that are described as being sized at a ratio as compared to another device may have a transconductance and output current that is larger or smaller at that ratio as compared to the transconductance of the other device. It will be appreciated that these transistor characteristics substantially affect how rapidly the output driver can change the output voltage when driving a capacitive load.

Further, the present disclosure may refer to a transistor as a “mirror” of another transistor. A transistor that “mirrors” another reference device may have a gate coupled to the gate of the reference device and a source that is coupled to the same node as the source of the reference device. Accordingly, the mirror device may be configured to source or sink a current that mirrors (i.e., duplicates) the current in the other device at a ratio that is dependent on the ratio of the respective sizes of the mirror device and the reference device.

Further, the present disclosure may refer to a “capacitive load.” A capacitive load may refer to the capacitive component of any load. Accordingly, for the purposes of the present disclosure, a capacitive load may refer to the capacitive component of a load having, for example, a resistive component and an inductive component as well the capacitive component. A capacitive load at the output of a digital output driver may include, for example, the gate capacitance of one or more transistors in one or more devices that are driven by the digital output driver and the parasitic capacitance of any metal lines that couple the digital output driver to the inputs of the other devices.

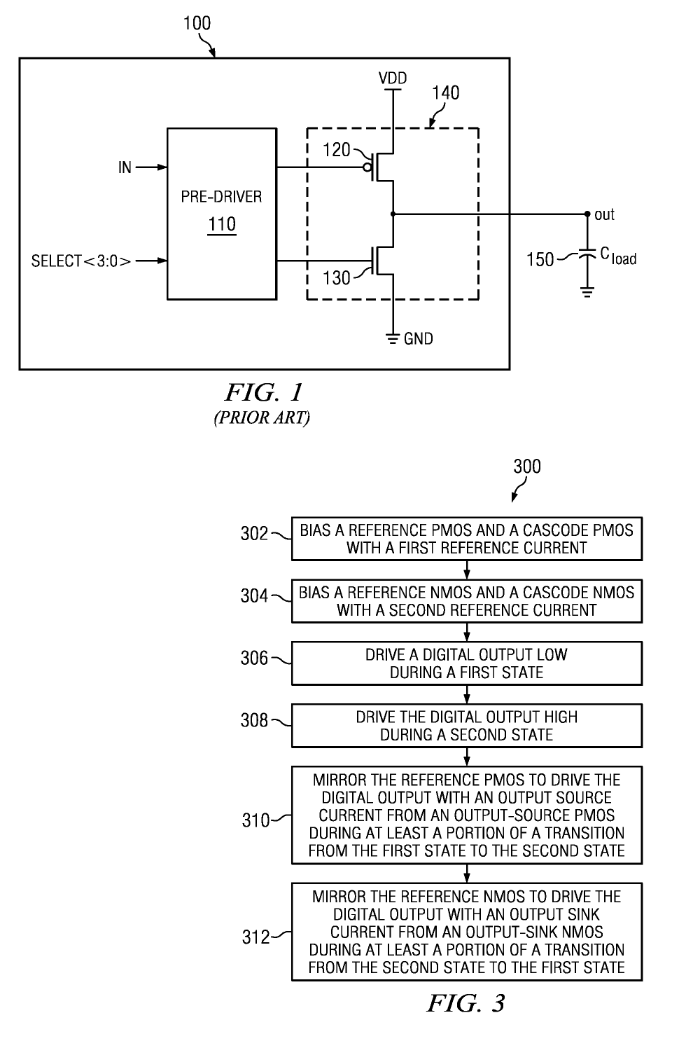

FIG. 1 illustrates a schematic diagram of an example digital output driver 100 as known in the art. Digital output driver 100 may include a pre-driver 110 and an output device array 140 having a PMOS 120 and an NMOS 130. Digital output driver may be configured to drive a capacitive load depicted by capacitor 150.

Pre-driver 110 may be configured to receive a digital input signal (IN) that may be intended to be buffered and communicated by digital output driver 100 to one or more other integrated circuits. Pre-driver 110 may be configured to drive an output device array 140 having a PMOS 120 and an NMOS 130. PMOS 120 may have a gate coupled to a first output of pre-driver 110 and a source coupled to a high potential power supply which, for the purposes of the present disclosure, may be referred to as VDD. NMOS 130 may have a gate coupled to a second output of pre-driver 110 and a source coupled to a low potential power supply which, for the purposes of the present disclosure, may be referred to as GND. PMOS 120 and NMOS 130 may have drains that may be coupled together and further coupled to the output of digital output driver 100.

The output of digital output driver 100 may be coupled to a capacitive load depicted by capacitor 150. The value of the capacitive load depicted by capacitor 150 may be determined by the application in which digital output driver 100 may be used. For example, digital output driver 100 may be configured to drive one or more digital inputs on other integrated circuits. Further, the output of digital output driver 100 may coupled to the digital inputs on other integrated circuits via off-chip metal routing. Each of the digital inputs may contribute to the capacitive load depicted by capacitor 150 along with the parasitic capacitance of any off-chip metal routing used to couple digital output driver 100 to the digital inputs on other integrated circuits.

To accommodate a range of potential capacitive loads that various instantiations of digital output driver 100 may be required drive, PMOS 120 and NMOS 130 in the output device array 140 may have selectable sizes. PMOS 120 may include an array of individual PMOS devices which may contribute to the total size of PMOS 120 when selected and driven by pre-driver 110. Similarly, NMOS 130 may include an array of individual NMOS devices which may contribute to the total size of NMOS 130 when selected and driven by pre-driver 110.

Pre-driver 110 may include a digital input SELECT<3:0>, which may be a four-bit digital input with sixteen potential input values. When SELECT<3:0> is set to higher values, a larger number of individual PMOS devices in PMOS 120 and a larger number of individual NMOS devices in NMOS 130 may be selected and driven by pre-driver 110. When a larger number of individual PMOS devices in PMOS 120 are selected and driven by pre-driver 110, the output drive capability of PMOS 120 may be larger, and PMOS 120 may be capable of driving higher capacitive loads at required low-to-high transition times for a digital signal driven at the output of digital output driver 100. Similarly, when a larger number of individual NMOS devices in NMOS 130 are selected and driven by pre-driver 110, the output drive capability of NMOS 130 may be larger, and NMOS 130 may be capable of driving higher capacitive loads at required high-to-low transition times for a digital signal driven at the output of digital output driver 100.

On the other hand, when SELECT<3:0> is set to lower values, a lower number of individual PMOS devices in PMOS 120 and a lower number of individual NMOS devices in NMOS 130 may be selected and driven by pre-driver 110. When a lower number of individual PMOS devices in PMOS 120 are selected and driven by pre-driver 110, the output drive capability of PMOS 120 may be lower, and PMOS 120 may only be capable of driving lower capacitive loads at required low-to-high transition times. Similarly, when a lower number of individual NMOS devices in NMOS 130 are selected and driven by pre-driver 110, the output drive capability of NMOS 130 may be lower, and NMOS 130 may only be capable of driving lower capacitive loads at required high-to-low transition times.

Accordingly, the setting of higher or lower values for SELECT<3:0> may correspond to the capacitive load that a particular instantiation of digital output driver 100 may be required to drive. SELECT<3:0> may be set to lower values when digital output driver 100 is configured to drive relatively smaller capacitive loads. Alternatively, SELECT<3:0> may be set to higher values when digital output driver 100 is configured to drive relatively larger capacitive loads.

The transition time of a digital signal driven by a digital output driver may depend not only on its capacitive load, but also upon internal characteristics of the digital output driver. Such characteristics may vary with factors including, for example, temperature, supply voltage, and/or semiconductor process variation. For example, the rise time of a digital signal driven by digital output driver 100 may depend primarily on the output drive capability of PMOS 120, which may vary significantly across temperature, supply voltage, and/or semiconductor process variation. Similarly, the fall time of a digital signal driven by digital output driver 100 may depend primarily on the output drive capability of NMOS 130, which may vary significantly across temperature, supply voltage, and/or semiconductor process variation. Such factors may also affect the rise and fall times of the outputs of pre-driver 110, which in turn may further affect the rise and fall times of a digital signal at the output of digital output driver 100. Lowering the variation of a digital output driver's rise and fall times due to factors such as temperature, supply voltage, and semiconductor process variation may allow the digital output driver to meet industry-standard rise-time and fall-time ranges for a larger range of capacitive loads.

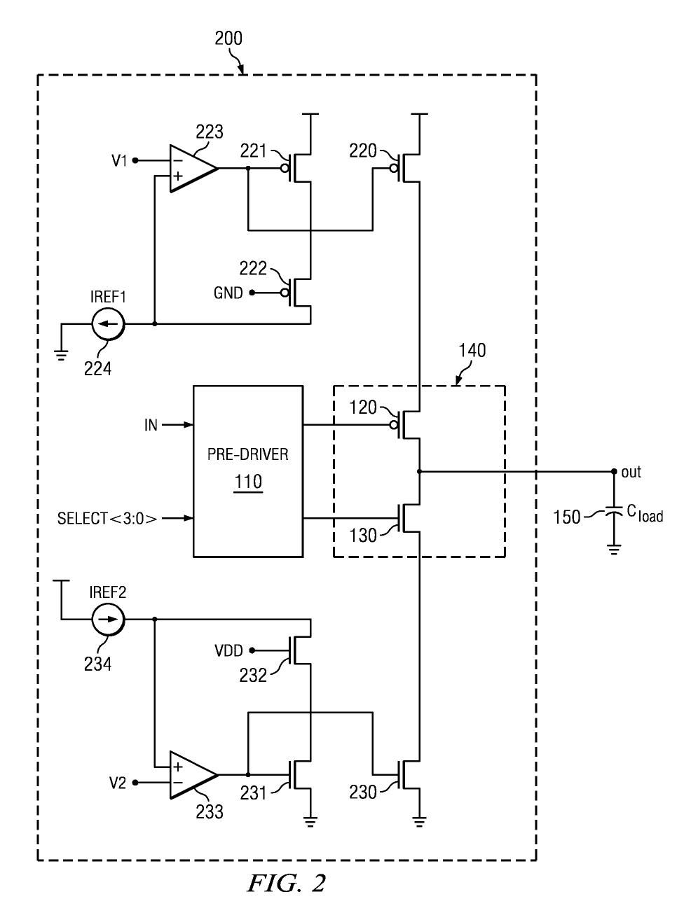

FIG. 2 illustrates a schematic diagram of a digital output driver 200, in accordance with certain embodiments of the present disclosure. Digital output driver 200 may be configured to drive a digital output with a constant-current source during low-to-high digital output transitions and a constant-current sink during high-to-low digital output transitions. The use of a constant-current source and a constant-current sink may improve the variation of the digital output transitions across factors including, for example, temperature, supply voltage, and semiconductor process variation.

Though the present disclosure may refer to a “constant-current” source or a “constant-current” sink, such currents need not be perfectly constant. A “constant-current,” as used herein, may refer to a current that is based on the mirroring of a reference current. Such mirrored currents may experience variation as compared to their reference due to factors such as semiconductor processing mismatch and/or imbalanced operating conditions.

Digital output driver 200 may include a pre-driver 110 and an output device array 140 having a PMOS 120 and an NMOS 130. Further, digital output driver 200 may include a PMOS 220, a PMOS 221, a PMOS 222, an amplifier 223, a current reference 224, an NMOS 230, an NMOS 231, an NMOS 232, an amplifier 233, and a current reference 234.

Pre-driver 110 may be configured to receive a digital input signal (IN) that may be intended to be buffered and communicated by digital output driver 200 to one or more other integrated circuits. Pre-driver 110 may be configured to drive an output device array 140 having a PMOS 120 and an NMOS 130. PMOS 120 may have a gate coupled to a first output of pre-driver 110, and NMOS 130 may have a gate coupled to a second output of pre-driver 110. PMOS 120 and NMOS 130 may have drains that may be coupled together and further coupled to the output of digital output driver 200. Pre-driver 110 may be configured to drive the gate of PMOS 120 and the gate of NMOS 130 at a high potential (e.g., equivalent to VDD) in order to drive the output of digital output driver 200 low when the IN signal is low. Pre-driver may be configured to drive the gate of PMOS 120 and the gate of NMOS 130 at a low potential (e.g., equivalent to GND) in order to drive the output of digital output driver 200 high when the IN signal is high.

The output of digital output driver 200 may be coupled to a capacitive load depicted by capacitor 150. The value of the capacitive load depicted by capacitor 150 may be determined by the application in which digital output driver 200 may be used. For example, digital output driver 200 may be configured to drive one or more digital inputs on one or more other integrated circuits. Further, the output of digital output driver 200 may coupled to the digital inputs on other integrated circuits via off-chip metal routing.

To accommodate a range of potential capacitive loads that various instantiations of digital output driver 200 may be required to drive, PMOS 120 and NMOS 130 in output device array 140 may have selectable sizes. PMOS 120 may include an array of individual PMOS devices which may contribute to the total size of PMOS 120 when those individual PMOS devices are selected and driven by pre-driver 110. The total size of PMOS 120 and, thus, the output drive capability of PMOS 120 may depend on how many individual PMOS devices are selected and driven by pre-driver 110. Similarly, NMOS 130 may include an array of individual NMOS devices which may contribute to the total size of NMOS 130 when selected and driven by pre-driver 110. The total size of NMOS 130 and, thus, the output drive capability of NMOS 130 may depend on how many individual NMOS devices are selected and driven by pre-driver 110.

Pre-driver 110 may include a digital select input which may be, for example, a four-bit digital input with sixteen potential input values (SELECT<3:0>). When SELECT<3:0> is set to higher values, a larger number of individual PMOS devices in PMOS 120 and a larger number of individual NMOS devices in NMOS 130 may be selected and driven by pre-driver 110. When a larger number of individual PMOS devices in PMOS 120 are selected and driven by pre-driver 110, the output drive capability of PMOS 120 may be larger, and PMOS 120 may be capable of driving higher capacitive loads at required low-to-high transition times. Similarly, when a larger number of individual NMOS devices in NMOS 130 are selected and driven by pre-driver 110, the output drive capability of NMOS 130 may be larger, and NMOS 130 may be capable of driving higher capacitive loads at required high-to-low transition times.

On the other hand, when SELECT<3:0> is set to lower values, a lower number of individual PMOS devices in PMOS 120 and a lower number of individual NMOS devices in NMOS 130 may be selected and driven by pre-driver 110. When a lower number of individual PMOS devices in PMOS 120 are selected and driven by pre-driver 110, the output drive capability of PMOS 120 may be lower, and PMOS 120 may only be capable of driving lower capacitive loads at required low-to-high transition times. Similarly, when a lower number of individual NMOS devices in NMOS 130 are selected and driven by pre-driver 110, the output drive capability of NMOS 130 may be lower, and NMOS 130 may only be capable of driving lower capacitive loads at required high-to-low transition times.

Accordingly, the setting of higher or lower values for SELECT<3:0> may correspond to the capacitive load that a particular instantiation of digital output driver 200 may be required to drive. SELECT<3:0> may be set to lower values when digital output driver 200 is configured to drive relatively smaller capacitive loads. Alternatively, SELECT<3:0> may be set to higher values when digital output driver 200 is configured to drive relatively larger capacitive loads.

As described above, digital output driver 200 may be configured to source a current onto its output during a low-to-high transition of the digital output. For example, digital output driver 200 may incorporate a current reference 224 that may sink a current IREF1 that may be mirrored to provide the constant-current source for the output of digital output driver 200. Current reference 224 may have a first terminal coupled to GND and a second terminal coupled to a drain of PMOS 222. PMOS 222 may have a gate coupled to GND and a source coupled to the drain of PMOS 221. PMOS 222 may be referred to as a cascode for PMOS 221. PMOS 221 may have a gate driven by an output of amplifier 223 and a source coupled to VDD. Amplifier 223 may have a negative input terminal coupled to a reference voltage V1 and a positive input terminal coupled to the drain of PMOS 222 and the second terminal of current reference 224. Accordingly, amplifier 223, PMOS 222, and PMOS 221 may be described as forming a feedback loop in which amplifier 223 may drive the gate of PMOS 221 sufficiently to source the IREF1 current that may be sunk by current reference 224 while the feedback voltage on the positive input terminal of amplifier 223 may be roughly equivalent to the reference voltage V1 on the negative input terminal of amplifier 223.

PMOS 220 may have a source coupled to VDD and a gate that is coupled to the gate of PMOS 221 and the output terminal of amplifier 223. Accordingly, PMOS 220 may mirror the reference current IREF1 sourced by PMOS 221. During a low-to-high transition of the output of digital output driver 200, PMOS 120 may be turned on, i.e., the gate of PMOS 120 may be driven low to a voltage equivalent to GND. Accordingly, during low-to-high transitions of the output of digital output driver 200, PMOS 120 may pass the mirrored version of IREF1 sourced by PMOS 220 to the output of digital output driver 200.

During low-to-high transitions of the output of digital output driver 200, the gate of PMOS 120 may be driven low to a voltage potential equivalent to GND similar to the gate of cascode PMOS 222. During this time, PMOS 120 may operate as a cascode for output PMOS 220 similar to the operation of PMOS 222 as a cascode for reference PMOS 221.

As described above, the feedback loop formed by amplifier 223, PMOS 221, and PMOS 222 may force the drain of PMOS 222 to a voltage potential equivalent to the voltage reference V1. Accordingly, the point at which the operating conditions of PMOS 220 and PMOS 120 most closely match the operating conditions of PMOS 221 and PMOS 222 may be when the output voltage is equivalent to V1. Thus, the cascoded output formed by PMOS 220 and PMOS 120 may most accurately mirror IREF1 when the output voltage is equivalent to V1.

When the output voltage is lower than V1, the cascoded output formed by PMOS 220 and PMOS 120 may operate in a constant-current mode where it may mirror IREF1 and provide a roughly constant-current to the output. On the other hand, when the output voltage is higher than V1, PMOS 120 and PMOS 220 may have insufficient drain-to-source voltages to operate as a current mirror, and the output current may be a function of the effective resistances of PMOS 120 and PMOS 220. Accordingly, the voltage potential at which digital output driver 200 shifts from a constant-current mode to a resistive mode during a low-to-high transition of the digital output may be controlled via the voltage reference V1.

As described above, the rise time of a digital output driving a capacitive load is a function of the drive current during the low-to-high transition. Accordingly, the variation of the rise time may be a function of the variation of the drive current during the low-to-high transition. As compared to a current that depends on the effective resistance of a PMOS device which may vary significantly with temperature, supply voltage, and/or semiconductor process variation, the IREF1 current may be relatively constant across temperature, supply voltage, and/or semiconductor process variation. Accordingly, the constant-current portion of the low-to-high transition may reduce the variation of the rise time of digital output driver 200 across factors such as temperature, supply voltage, and/or semiconductor process variation.

Further, the voltage reference V1 may be relatively constant over temperature, supply voltage, and/or semiconductor process variation. Accordingly, controlling the output voltage at which PMOS 120 and PMOS 220 shift from a constant-current mode to a resistive mode via voltage reference V1 may further reduce the variation of the rise time of digital output driver 200 across factors such as temperature, supply voltage, and/or semiconductor process variation.

As described above, the size of PMOS 120 may be selected based on the SELECT<3:0> signal corresponding to a capacitive load setting for digital output driver 200. In some embodiments, the source current provided by PMOS 220 during at least the constant-current portion of the low-to-high transition may also be selected based on a select signal (e.g., SELECT<3:0>) corresponding to a capacitive load setting for digital output driver 200. In some embodiments, the reference current, IREF1, upon which the current sourced by PMOS 220 is based, may be adjusted based on SELECT<3:0>. For example, for higher settings of SELECT<3:0> corresponding to higher capacitive load settings, IREF1 may provide higher reference currents and PMOS 220 may, in turn, source higher currents during the low-to-high transition of the output of digital output driver 200. On the other hand, for lower settings of SELECT<3:0> corresponding to lower capacitive load settings, IREF1 may provide lower reference currents and PMOS 220 may, in turn, source lower currents during the low-to-high transition of the output of digital output driver 200. In some embodiments, PMOS 220 may have a selectable size based on the SELECT<3:0> signal. For example, for higher settings of SELECT<3:0> corresponding to higher capacitive load settings, PMOS 220 may have larger selected sizes and may mirror IREF1 at a larger ratio and, thus, PMOS 220 may source higher currents during the low-to-high transition of the output of digital output driver 200. On the other hand, for lower settings of SELECT<3:0> corresponding to lower capacitive load settings, PMOS 220 may have lower selected sizes and may mirror IREF1 at a lower ratio and, thus, PMOS 220 may source lower currents during the low-to-high transition of the output of digital output driver 200.

As described above, digital output driver 200 may be configured to sink a current from its output during a high-to-low transition of the digital output signal. For example, digital output driver 200 may incorporate a current reference 234 that may sink a current IREF2 that may be mirrored to provide the constant-current sink for the output of digital output driver 200. Current reference 234 may have a first terminal coupled to VDD, and a second terminal coupled to a drain of NMOS 232. NMOS 232 may have a gate coupled to VDD and a source coupled to the drain of NMOS 231. NMOS 232 may be referred to as a cascode for NMOS 231. NMOS 231 may have a gate driven by an output of amplifier 233 and a source coupled to GND. Amplifier 233 may have a negative input terminal coupled to a reference voltage V2 and a positive input terminal coupled to the drain of NMOS 232 and the second terminal of current reference 234. Accordingly, amplifier 233, NMOS 232, and NMOS 231 may form a loop in which amplifier 233 drives the gate of NMOS 231 sufficiently to sink the IREF2 current that is sourced by current reference 234 while the feedback voltage on the positive input terminal of amplifier 233 is roughly equivalent to the reference voltage V2 on the negative input terminal of amplifier 233.

NMOS 230 may have a source coupled to GND and a gate that is coupled to the gate of NMOS 231 and the output terminal of amplifier 233. Accordingly, NMOS 230 may mirror the reference current IREF2 sunk by NMOS 231. During a high-to-low transition of the output of digital output driver 200, NMOS 130 may be turned on, i.e., the gate of NMOS 130 may be driven high to a voltage equivalent to VDD. Accordingly, during high-to-low transitions of the output of digital output driver 200, NMOS 130 may pass the mirrored version of IREF2 sunk by NMOS 230 from the output of digital output driver 200.

During high-to-low transitions of the output of digital output driver 200, the gate of NMOS 130 may be driven high to a voltage potential equivalent to VDD similar to the gate of cascode NMOS 232. During this time, NMOS 130 may operate as a cascode for output NMOS 230 similar to the operation of NMOS 232 as a cascode for reference NMOS 231.

As described above, the feedback loop formed by amplifier 233, NMOS 231, and NMOS 232 may force the drain of NMOS 232 to a voltage potential equivalent to the voltage reference V2. Accordingly, the point at which the operating conditions of NMOS 230 and NMOS 130 most closely match the operating conditions of NMOS 231 and NMOS 232 may be when the output voltage is equivalent to V2. Thus, the cascoded output formed by NMOS 230 and NMOS 130 may most accurately mirror IREF2 when the output voltage is equivalent to V2.

When the output voltage is higher than V2, the cascoded output formed by NMOS 230 and NMOS 130 may operate in a constant-current mode where it may mirror IREF2 and sink a roughly constant-current from the output. On the other hand, when the output voltage is lower than V2, NMOS 130 and NMOS 230 may have insufficient drain-to-source voltages to operate as a current mirror, and the output current may be a function of the effective resistances of NMOS 130 and NMOS 230. Accordingly, the voltage potential at which digital output driver 200 shifts from a constant-current mode to a resistive mode during a high-to-low transition of the digital output may be controlled via the voltage reference V2.

As described above, the fall time of the digital output driving a capacitive load is a function of the drive current during the high-to-low transition. Accordingly, the variation of the fall time may be a function of the variation of the drive current during the high-to-low transition. As compared to a current that depends on the effective resistance of an NMOS device which may vary significantly with temperature, supply voltage, and/or semiconductor process variation, the IREF2 current may be relatively constant across temperature, supply voltage, and/or semiconductor process variation. Accordingly, the constant-current portion of the high-to-low transition may reduce the variation of the fall time of digital output driver 200 across factors such as temperature, supply voltage, and/or semiconductor process variation.

Further, the voltage reference V2 may be relatively constant over temperature, supply voltage, and/or semiconductor process variation. Accordingly, controlling the output voltage at which NMOS 130 and NMOS 230 shift from a constant-current mode to a resistive mode via voltage reference V2 may further reduce the variation of the fall time of digital output driver 200 across factors such as temperature, supply voltage, and/or semiconductor process variation.

As described above, the size of NMOS 130 may be selected based on the SELECT<3:0> signal corresponding to a capacitive load setting for digital output driver 200. In some embodiments, the sink current provided by NMOS 230 during at least the constant-current portion of the high-to-low transition may also be selected based on a select signal (e.g., SELECT<3:0>) corresponding to a capacitive load setting for digital output driver 200. In some embodiments, the reference current, IREF2, upon which the current sunk by NMOS 230 is based, may be selected based on SELECT<3:0>. For example, for higher settings of SELECT<3:0> corresponding to higher capacitive load settings, IREF2 may provide higher reference currents and NMOS 230 may in turn sink higher currents during the high-to-low transition of the output of digital output driver 200. On the other hand, for lower settings of SELECT<3:0> corresponding to lower capacitive load settings, IREF2 may provide lower reference currents and NMOS 230 may, in turn, sink lower currents during the high-to-low transition of the output of digital output driver 200. In some embodiments, NMOS 230 may have a selectable size based on the SELECT<3:0> signal. For example, for higher settings of SELECT<3:0> corresponding to higher capacitive load settings, NMOS 230 may have larger selected sizes and may mirror IREF2 at larger ratios and, thus, NMOS 230 may source higher currents during the high-to-low transition of the output of digital output driver 200. On the other hand, for lower settings of SELECT<3:0> corresponding to lower capacitive load settings, NMOS 230 may have lower selected sizes and may mirror IREF2 at a lower ratio and, thus, NMOS 230 may sink lower currents during the high-to-low transition of the output of digital output driver 200.

FIG. 3 illustrates a flow chart of a method 300 for driving a digital output with a capacitive load.

At step 302, current reference 224 may bias a reference PMOS 221 and a cascode PMOS 222 with a first reference current IREF1. The gate of reference PMOS 221 may be driven by amplifier 223. At step 304, current reference 234 may bias a reference NMOS 231 and a cascode NMOS 232 with a first reference current IREF2. The gate of reference NMOS 231 may be driven by amplifier 233.

At step 306, digital output driver 200 may drive a digital output low during a first state, in part by driving the gate of PMOS 120 and the gate of NMOS 130 high. At step 308, digital output driver 200 may drive the digital output high during a second state, in part by driving the gate of PMOS 120 and the gate of NMOS 130 low.

At step 310, current-source PMOS 220 may mirror reference PMOS 221 to drive the digital output with an output-source current during at least a portion of a transition from the first state to the second state.

At step 312, current-sink NMOS 230 may mirror reference NMOS 231 to drive the digital output with an output-sink current during at least a portion of a transition from the second state to the first state.

Although FIG. 3 discloses a particular number of steps to be taken with respect to method 300, method 300 may be executed with greater or lesser steps than those depicted in FIG. 3. In addition, although FIG. 3 discloses a certain order of steps to be taken with respect to method 300, the steps comprising method 300 may be completed in any suitable order.

Although the present disclosure has been described with several embodiments, various changes and modifications may be suggested to one skilled in the art. It is intended that the present disclosure encompass such changes and modifications and fall within the scope of the appended claims.

What is claimed is:

1. A digital output driver, comprising:
a pre-driver configured to:
receive a digital input signal;
drive a first p-type Metal-Oxide Semiconductor Field Effect Transistor (PMOS) based at least on the digital input signal; and
drive a first n-type Metal-Oxide Semiconductor Field Effect Transistor (NMOS) based at least on the digital input signal; and
at least one of:
an output-source PMOS configured to provide an output-source current during at least a portion of a low-to-high transition of an output of the digital output driver, wherein the output-source PMOS is configured to mirror a reference PMOS that is configured to be driven at its gate by a first amplifier, to be biased by a first reference current, and to be cascoded by a cascode PMOS; and
an output-sink NMOS configured to provide an output-sink current during at least a portion of a high-to-low transition of the output of the digital output driver, wherein the output-sink NMOS is configured to mirror a reference NMOS that is configured to be driven at its gate by a second amplifier, to be biased by a second reference current, and to be cascoded by a cascode NMOS.

2. The digital output driver of claim 1, wherein:
the pre-driver is configured to drive a gate of the first PMOS and a gate of the first NMOS at a high potential during a first state and to drive the gate of the first PMOS and the gate of the first NMOS at a low potential during a second state;
a gate of the cascode PMOS is driven at the low potential; and
a gate of the cascode NMOS is driven at the high potential.

3. The digital output driver of claim 2, wherein:
a gate of the output-source PMOS and the gate of the reference PMOS are coupled to an output of the first amplifier;
a drain of the reference PMOS is coupled to a source of the cascode PMOS;
a drain of the cascode PMOS is coupled to a positive input of the first amplifier;
a first voltage reference is coupled to a negative input of the first amplifier;
a gate of the output-sink NMOS and the gate of the reference NMOS are coupled to an output of the second amplifier;
a drain of the reference NMOS is coupled to a source of the cascode NMOS;
a drain of the cascode NMOS is coupled to a positive input of the second amplifier; and
a second voltage reference is coupled to a negative input of the second amplifier.

4. The digital output driver of claim 1, wherein the pre-driver is configured to receive a select signal corresponding to a capacitive load setting of the digital output driver.

5. The digital output driver of claim 4, wherein at least one of the first PMOS and the first NMOS has a selectable size based at least on the select signal.

6. The digital output driver of claim 4, wherein at least one of the magnitude of the output-source current and the magnitude of the output-sink current is based at least on the select signal.

7. The digital output driver of claim 6, wherein at least one of the magnitude of the first reference current and the magnitude of the second reference current is based at least on the select signal.

8. The digital output driver of claim 7, wherein at least one of the ratio of the size of the output-source PMOS to the reference PMOS and the ratio of the size of the output-sink NMOS to the size of the reference NMOS is selectable based at least on the select signal.

9. A method of driving a digital output signal on a capacitive load, comprising:
biasing a reference p-type Metal-Oxide Semiconductor Field Effect Transistor (PMOS) and a cascode PMOS with a first reference current, wherein the reference PMOS is driven at its gate by a first amplifier;
biasing a reference n-type Metal-Oxide Semiconductor Field Effect Transistor (NMOS) and a cascode NMOS with a second reference current, wherein the reference NMOS is driven at its gate by a second amplifier;
driving a digital output low during a first state;
driving the digital output high during a second state;
mirroring the reference PMOS to drive the digital output with an output-source current from an output-source PMOS during at least a portion of a transition from the first state to the second state; and
mirroring the reference NMOS to drive the digital output with an output-sink current from an output-sink NMOS during at least a portion of a transition from the second state to the first state.

10. The method of claim 9, comprising:
driving a gate of a first PMOS and a gate of a first NMOS at a high potential during the first state;
driving the gate of the first PMOS and the gate of the first NMOS at a low potential during the second state;
driving a gate of the cascode PMOS at the low potential; and
driving a gate of the cascode NMOS at the high potential.

11. The method of claim 10, wherein:
a negative input of a first amplifier is driven by a first reference voltage;
an output of the first amplifier is coupled to a gate of the reference PMOS and a gate of the output-source PMOS;
a drain of the reference PMOS is coupled to a source of the cascode PMOS;
a drain of the cascode PMOS is coupled to a positive input of the first amplifier;
a negative input of a second amplifier is driven by a second reference voltage;
an output of the second amplifier is coupled to a gate of the reference NMOS and a gate of the output-sink NMOS;
a drain of the reference NMOS is coupled to a source of the cascode NMOS; and
a drain of the cascode NMOS is coupled to a positive input of the second amplifier.

12. The method of claim 10, comprising receiving a select signal corresponding to a capacitive load setting of the digital output driver.

13. The method of claim 12, wherein at least one of the first PMOS and the first NMOS has a selectable size based at least on the select signal.

14. The method of claim 12, wherein at least one of the magnitude of the output-source current and the magnitude of the output-sink current is based at least on the select signal.

15. The method of claim 14, wherein at least one of the magnitude of the first reference current and the magnitude of the second reference current is based at least on the select signal.

16. The method of claim 14, wherein at least one of the ratio of the size of the output-source PMOS to the reference PMOS and the ratio of the size of the output-sink NMOS to the size of the reference NMOS is selectable based at least on the select signal.
